(19) United States
(12) Patent Application Publication
(10) Pub. No.: US 2019/0071776 A1
(43) Pub. Date: Mar. 7, 2019

(54) INTERCHANGEABLE HOT FILAMENTS CVD REACTOR

(71) Applicant: ICDAT, Ltd., Nesher (IL)

(72) Inventor: Dimitry Boguslavsky, Haifa (IL)

(21) Appl. No.: 15/694,854

(22) Filed: Sep. 4, 2017

(51) Int. Cl. C23C 16/455; C23C 16/40; C23C 16/54; H01J 37/32

(52) U.S. Cl. CPC C23C 16/45565; C23C 16/402; H01J 37/3244; C23C 16/54; C23C 16/45521

(57) ABSTRACT

A reactor for a hot filament CVD, the reactor may include an array of filaments; a substrate support unit that is configured to support at least one substrate; a chamber that comprises multiple openings; a gas flow control unit that is coupled to the multiple openings and is configured to receive one or more CVD gases and direct the one or more CVD gases at one or more predefined directions within an energizing region formed by the array of filaments; and a movement system that is configured to introduce a movement between the array of filaments and the substrate support unit thereby selectively moving the at least one substrate in the energizing region and out of the energizing region.

### TECHNOLOGICAL FIELD

The presently disclosed subject matter relates to a reactor and process for diamond chemical vapor deposition (CVD) on substrates.

### BACKGROUND

Chemical vapor deposition (CVD) can be used to produce a synthetic diamond (www.wikipedia.org) by creating the circumstances necessary for carbon atoms in a gas to settle on a substrate in crystalline form.

CVD production of diamonds has received a great deal of attention in the materials sciences because it allows many new applications of diamonds that had previously been considered too difficult to make economical. CVD diamond growth typically occurs under low pressure (1-27 kPa; 0.145-3.926 psi; 7.5-203 Torr) and involves feeding varying amounts of gases into a chamber, energizing them and providing conditions for diamond growth on the substrate. The gases always include a carbon source, and typically include hydrogen as well, though the amounts used vary greatly depending on the type of diamond being grown.

One of the energy sources is a hot filament. The hot filament is intended to generate a plasma in which the gases are broken down (to radicals) and more complex chemistries occur.

One prior art CVD system directs H₂ and CH₄ gases towards a grid of linear filaments. The grid of liner filaments is heated to about 2000 degree Celsius. The substrate may be maintained at a temperature of between 600 to 1000 degrees Celsius.

### SUMMARY

There may be provided a reactor for a hot filament chemical vapor deposition (CVD), the reactor may include: an array of filaments; a substrate support unit that may be configured to support at least one substrate; a chamber that may include multiple openings; a gas flow control unit that may be coupled to the multiple openings and may be configured to receive one or more CVD gases and direct the one or more CVD gases at one or more predefined directions within an energizing region formed by the array of filaments; and a movement system that may be configured to introduce a movement between the array of filaments and the substrate support unit thereby selectively moving the at least one substrate in the energizing region and out of the energizing region.

The reactor may include cooling system that may include cooling fluid conduits that may be positioned within a filament support unit.

The movement system may be configured to scan the array of substrates in relation to the energizing region thereby exposing, at different points of time, different parts of the substrate to the energizing region.

The movement system may be configured to scan the array of substrates in relation to the energizing region thereby evenly exposing, at different points of time, different parts of the substrate to the energizing region.

The at least one substrate may include substrates that may be arranged in linear arrays and wherein the movement system may be configured to introduce a movement between the linear arrays of substrates and the array of filaments; wherein during at least a part of the movement the filaments of the array of filaments may be positioned between the linear arrays of the substrate.

The movement system may be adapted to rotate at least two substrates of the linear arrays.

The movement system may be adapted to rotate at least two substrates of the linear arrays about a rotation axis that may be normal to the movement between the linear arrays and the array of filaments.

The movement system may be adapted to independently control a rotation of at least two substrates of the linear arrays.

The gas flow control unit may include gas conduits that may include at least one gas conduit that has at least one opening, wherein the movement system may be configured to position, at least during one point in time the at least one gas conduit between the linear arrays; wherein the at least one gas conduit may be configured to selectively disperse at least one CVD gas between the linear arrays.

The reactor may include a sensor, wherein the sensor may be configured to generate an indication about a distance between at least one filament of the array and between at least one substrate.

The sensor may be a heat sensor that may be thermally coupled to a substrate of the at least one substrate.

The reactor may include a controller that may be configured to control the movement system based on the indication about the distance.

The reactor may include a controller that may be configured to control a heat outputted by the filament based on the indication about the distance.

The reactor may include a controller and multiple sensors, the multiple sensors may be configured to sense CVD conditions and the controller may be configured at least one of the movement system, gas flow control unit and the array of filaments based on CVD conditions sensed by the multiple sensors.

The CVD conditions may be selected out of a temperature of the array of filaments, a temperature of the at least one substrate, a flow of the CVD gases, and a spatial relationship between the array of filaments and the substrate support unit.

The reactor may include a group of interchangeable adaptors that may be removably coupled to the chamber; wherein a first interchangeable adaptor of the group may be mechanically coupled to the array of filaments; wherein a second interchangeable adaptor of the group may be mechanically coupled to the substrate support unit

The chamber may include interfaces for interfacing with each one of the group of interchangeable adaptors; wherein the interfaces may be equal to each other.

There may be provided a method for hot filament chemical vapor deposition (CVD) on at least one substrates, the method may include: supporting, by a substrate support unit, at least one substrate; forming, by an array of filaments, positioned in the reactor, an energizing region; receiving, by a gas flow control unit that may be coupled to multiple openings of a reactor, one or more CVD gases; directing, by the flow control unit, the one or more CVD gases at one or more predefined directions within the energizing region; and introducing movement, by a movement system, between the array of filaments and the substrate support unit thereby selectively moving the at least one substrate in the energizing region and out of the energizing region.

The method may include cooling the substrate support unit by a cooling system that may include cooling fluid conduits that may be positioned within the filament support unit.

The introducing movement may include scanning the array of substrates in relation to the energizing region thereby exposing, at different points of time, different parts of the substrate to the energizing region.

The introducing movement may include scanning the array of substrates in relation to the energizing region thereby evenly exposing, at different points of time, different parts of the substrate to the energizing region.

The at least one substrate may include substrates that may be arranged in linear arrays and wherein the method may include introducing movement between the linear arrays of substrates and the array of filaments; wherein during at least a part of the movement the filaments of the array of filaments may be positioned between the linear arrays of the substrate.

The method may include rotating, by the movement system, at least two substrates of the linear arrays.

The method may include rotating, by the movement system, at least two substrates of the linear arrays about a rotation axis that may be normal to the movement between the linear arrays and the array of filaments.

The method may include independently controlling, by the movement system, a rotation of at least two substrates of the linear arrays.

The gas flow control unit may include gas conduits that may include at least one gas conduit that has at least one opening, wherein the method may include positioning by the movement system, at least during one point in time the at least one gas conduit between the linear arrays; wherein the method may include selectively dispersing at least one CVD gas between the linear arrays.

The method may include generating by a sensor an indication about a distance between at least one filament of the array and between at least one substrate.

The sensor may be a heat sensor that may be thermally coupled to a substrate of the at least one substrate.

The method may include controlling, by a controller, the movement system based on the indication about the distance.

The method may include controlling, by a controller, a heat outputted by the filament based on the indication about the distance.

The method may include sensing by multiple sensors, CVD conditions, and controlling, by a controller, at least one of the movement system, gas flow control unit and the array of filaments based on CVD conditions sensed by the multiple sensors.

The CVD conditions may be selected out of a temperature of the array of filaments, a temperature of the at least one substrate, a flow of the CVD gases, and a spatial relationship between the array of filaments and the substrate support unit.

The method may include selecting one or more selected interchangeable adaptors out of a group of interchangeable adaptors that may be removably coupled to the chamber; wherein a first interchangeable adaptor of the group may be mechanically coupled to the array of filaments; wherein a second interchangeable adaptor of the group may be mechanically coupled to the substrate support unit

The chamber may include interfaces for interfacing with each one of the group of interchangeable adaptors; wherein the interfaces may be equal to each other.

### BRIEF DESCRIPTION OF THE DRAWINGS

In order to better understand the subject matter that is disclosed herein and to exemplify how it may be carried out in practice, embodiments will now be described, by non-limiting example only, with reference to the accompanying drawings, in which:

FIG. 1 illustrates an example of a HF CVD reactor system, in an assembled state;

FIG. 2 illustrates an example of a reactor chamber of the reactor shown in FIG. 1, and its substrates door and filaments door unassembled with the chamber;

FIG. 3 is an enlarged view of the reactor chamber shown in FIG. 2;

FIG. 4 illustrates examples of a substrate module;

FIGS. 5A and 5B illustrate examples of filaments modules;

FIG. 6A is an example of a side view of an interior of a reactor chamber

FIG. 6B illustrates an example of a top view of the interior of the reactor chamber shown in FIG. 6A;

FIG. 6C illustrates an example of an exploded view of a reactor that includes a gas distribution system;

FIGS. 7A and 7B illustrate examples of substrate modules;

FIG. 8 illustrates an example of a fluid cooling system;

FIG. 9 illustrates an example of filaments, substrates holders, a substrates stage, filaments, one or more sensors and a controller;

FIG. 10 illustrates an example of filaments, substrates holders, a substrates stage, and filaments;

FIG. 11 illustrates an example of filaments, substrates holders, a substrates stage, and filaments;

FIG. 12 illustrates an example of filaments, substrates holders, a substrates stage, filaments, one or more sensors and a controller;

FIG. 13 is an example of a method;

FIG. 14 illustrates examples of a substrate module; and

FIG. 15 is an example of the reactor chamber.

### DETAILED DESCRIPTION OF EMBODIMENTS

Embodiments of the presently disclosed subject matter refer to a number of specific features of a reactor configured to perform a diamond HF CVD (hot filaments chemical vapor deposition) process on a plurality of substrates and to corresponding specific aspects of such process, which otherwise generally is as described in the Background. The specific features of the reactor of the presently disclosed subject matter are generally directed to allow the reactor to be used for performing the process successively on a number of sets of substrates at reduced time required for replacing a set of already processed substrates with a new one yet to be processed, and to allow the same basic structure of the reactor to be used for different applications, i.e. for performing diamond HF CVD on different kinds of substrates including those requiring 2D processing, such as e.g. planar semiconductor wafers, and 3D processing, such as e.g. elongated cutting tools.

Thus, the reactor basically comprises a reactor chamber having all functional components required to perform the HF CVD process, i.e. components allowing to hold the substrates and filament wires (hereinafter: filaments) in a desired mutual disposition, to manipulate the substrates when needed and to electrically heat the filaments to a required high temperature, to introduce gas into the chamber and apply vacuum to the chamber so as to allow gas introduced into its interior to flow across the filaments and to be disassociated into gas radicals.

The reactor chamber has an interior defined by its peripheral wall having two openings, which in operation are sealingly closed by two doors, one—holding the filaments and constituting a part of a filaments module, and the other—holding the substrates and constituting a part of the substrate module. The peripheral wall is further formed with gas introduction and vacuum ports connectable to respective gas and vacuum pumps, and one or more additional chamber ports that can be used for viewing the process, and/or mounting therein sensor/s allowing to obtain information regarding parameters of the process within the interior of the chamber.

Regarding the filaments module, though in general the reactor chamber can have a set of such modules for use in different applications, one such module can be sufficient if it is configured to allow the filaments held therein to be replaced when needed, e.g. for use in a new application, i.e. for processing a new kind of substrates, requiring a different arrangement of the filaments. For each application, the filaments can be held on the corresponding door in a desired manner by suitable filaments holding arrangement, which can be mounted to the door and which can be associated with other functional components that may or may not be also mounted to the door. Such components can include but are not limited to means for applying heating electric current to the filaments, thereby creating a high heat zone in the reactor chamber, means for tensioning the filament if and when needed, etc. Filaments modules in the reactor according to the presently disclosed subject matter can be configured to maintain a predefined tension of the filaments during preparation and the CVD processes.

Regarding the substrate module, it can be in the form of one of a plurality of interchangeable substrate modules each comprising its own door configured for holding a plurality of substrates thereon. The doors of all the such substrate modules can have identical or similar general exterior design allowing each of them to be mounted in the same manner in the corresponding opening of the reactor chamber, though they can differ in the manner the substrates are held thereby and other associated components depending on the kind of the substrates and the manner they need to be processed. The modules can be fully identical when there is a need to process a number of sets of identical substrates, e.g. in a mass production process, in which case the number of substrates in a set held by each module constitutes a part of the entire series to be processed.

The reactor chamber, its doors and the filament module and the substrate modules can be configured so that when the reactor chamber is fully assembled, i.e. when both doors with the corresponding modules sealingly close the two openings of the chamber, the filaments are disposed above the substrates. For example, the filaments can be disposed in an upper part of the reactor chamber and the substrates can be disposed in a lower part of the reactor chamber.

The substrate modules can be configured for moving the substrates relative to the substrates door, in the direction towards and/or away from the filaments and a high heat zone associated therewith. Since the efficiency of the HF CVD process is affected by the number of radicals that reach the substrates, bringing the substrates closer to the high heat zone, can allow to increase the amount of radicals that can reach the substrates prior to undergoing a recombination that neutralizes the radicals and becoming ineffective. On the other hand, since the substrates can be sensitive to high temperature required to increase the amount of radicals produced, at least at some stages of the process the substrates can be kept at a distance from the high heat zone ensuring protection of the substrates from the damaging heat. This particularly concerns preparation stages of the process, such as filaments conditioning. Alternatively, or in addition, the substrate modules can further comprise a cooling system to protect the substrates from overheating.

Since the HF-CVD process and, optionally, some of its preparation stages, require gas to flow in between the heated filaments, the gas introduction ports and the vacuum ports in the reactor chamber are disposed so as to produce a differential gas pressure in the corresponding desired direction. More particular, the reactor chamber can be provided with a gas distribution system configured for the introduction of gas into the reactor chamber, e.g. at its upper part, and for the extraction of gas out of the chamber by vacuum, e.g. at its lower part, and comprising the above ports and other possible components, whose mutual disposition and parameters can be selected so as to generate gas flow patterns in and around both the filament and the substrates to optimize deposition rates, as well as coating uniformity and quality, whilst the reactor chamber can be configured to provide adequate space to avoid undesirable gas recombination at the chamber inner surfaces.

The gas can be a mixture of gas types prepared outside the reactor or can be mixed within the chamber by introducing separate gas compositions therein.

The reactor can further be connectable to or comprise an electric source to provide electric current required for the operation of its systems such as, for example, those responsible for heating the filaments, and for measuring process conditions, e.g. the temperature of the filaments, substrates, and other sensors.

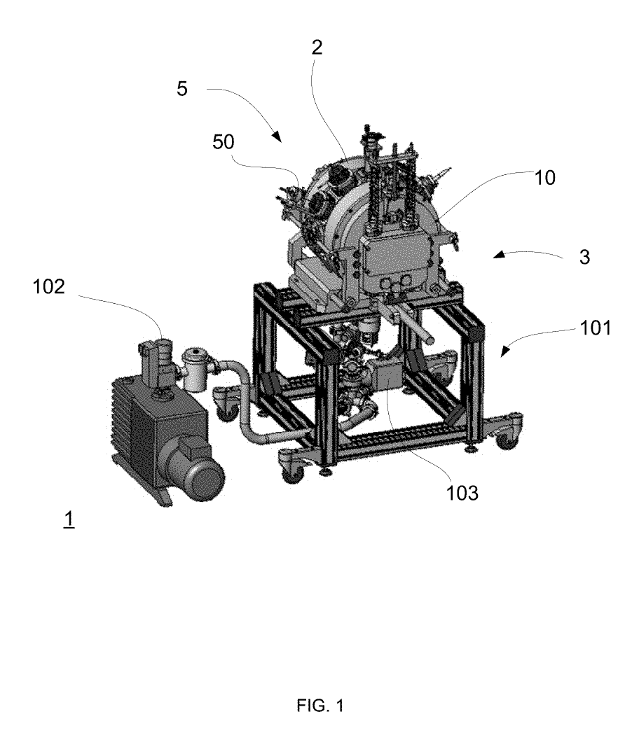

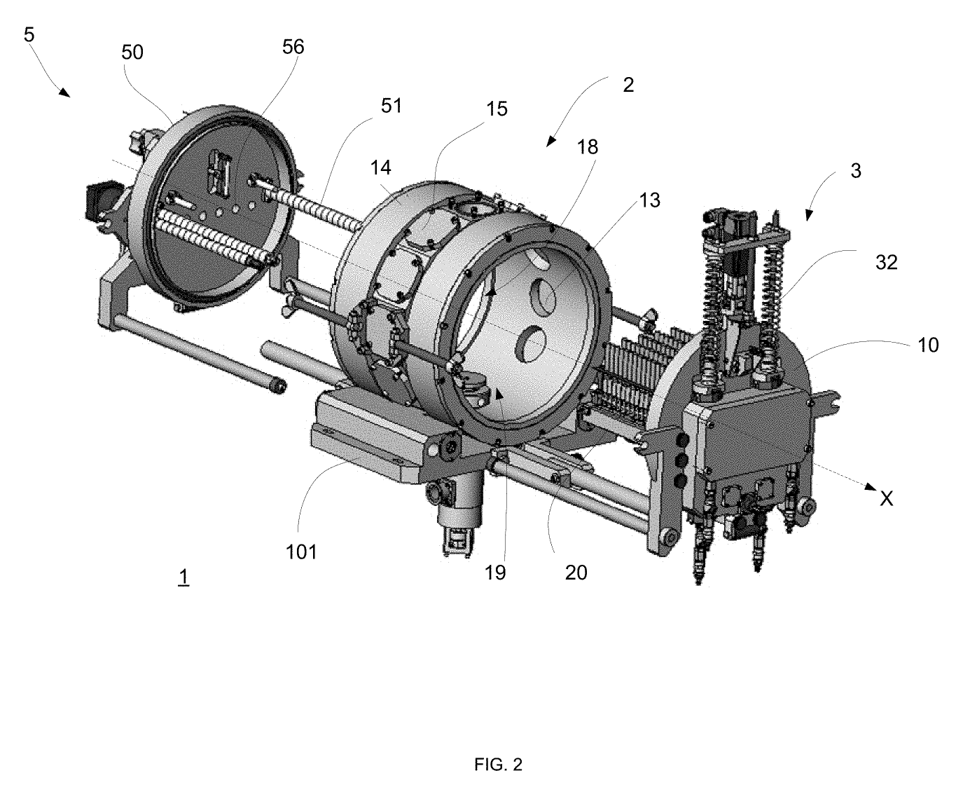

One example of a reactor of the kind generally described above is shown in FIGS. 1 and 2, where the reactor is designated as 1 and its chamber is designated as 2, and where the reactor 1 is shown to further comprise a base 101 supporting the reactor chamber 2, a gas pump 103, and a vacuum pump 102.

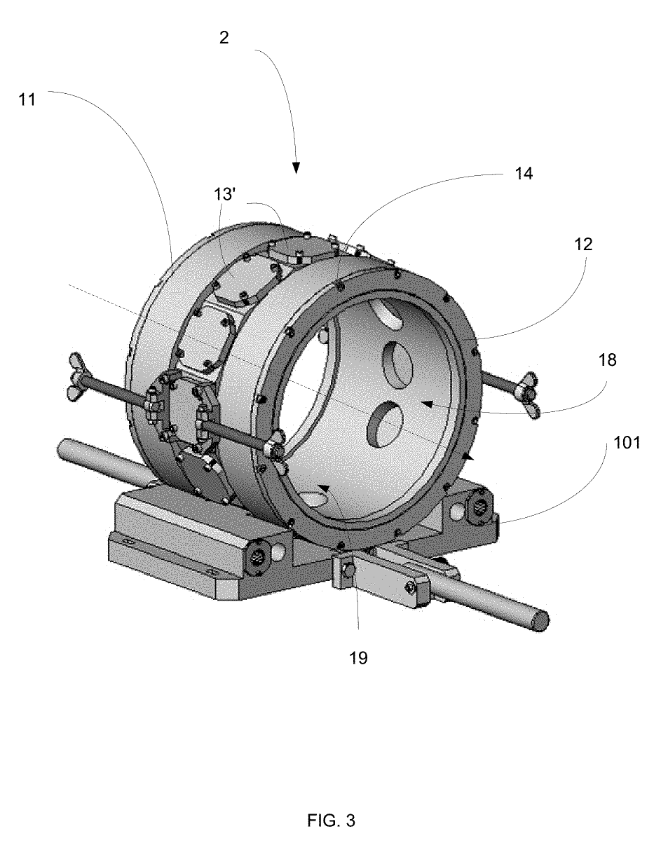

The reactor chamber 2 in this example as best seen in FIG. 3, comprises a peripheral wall 14, which is generally cylindrical and has two open ends 11 and 12 spaced along a horizontal axis X of the chamber horizontally dividing the chamber into an upper part 18 and a lower part 19. It needs to be noted that the chamber does not necessarily need to be cylindrical, but rather can have any regular, possibly axisymmetric shape.

The open end 12 of the chamber is the one, to which a filaments module generally designated as 5 is mounted at least in operation, so as to sealingly close the end 12 as shown in FIG. 1. The door 50 of the filament module 5 is configured for interchangeably assembling thereto one of a number of filaments stages each bearing an array of filaments installed thereon (not seen in FIG. 1 and not shown in FIG. 2). The filament stages can have different designs, e.g. can be configured for different manners and orientations, in which the filaments are mounted, and/or different numbers of their rows and columns, and/or different numbers of filaments in each row and/or columns, different horizontal and/or vertical distances between the filaments, etc. depending on the application, for which the process is to be performed. The filaments door 50 can be configured for replacing the filament stages with or without fully dissembling the door from the open end 12 of the chamber 2.

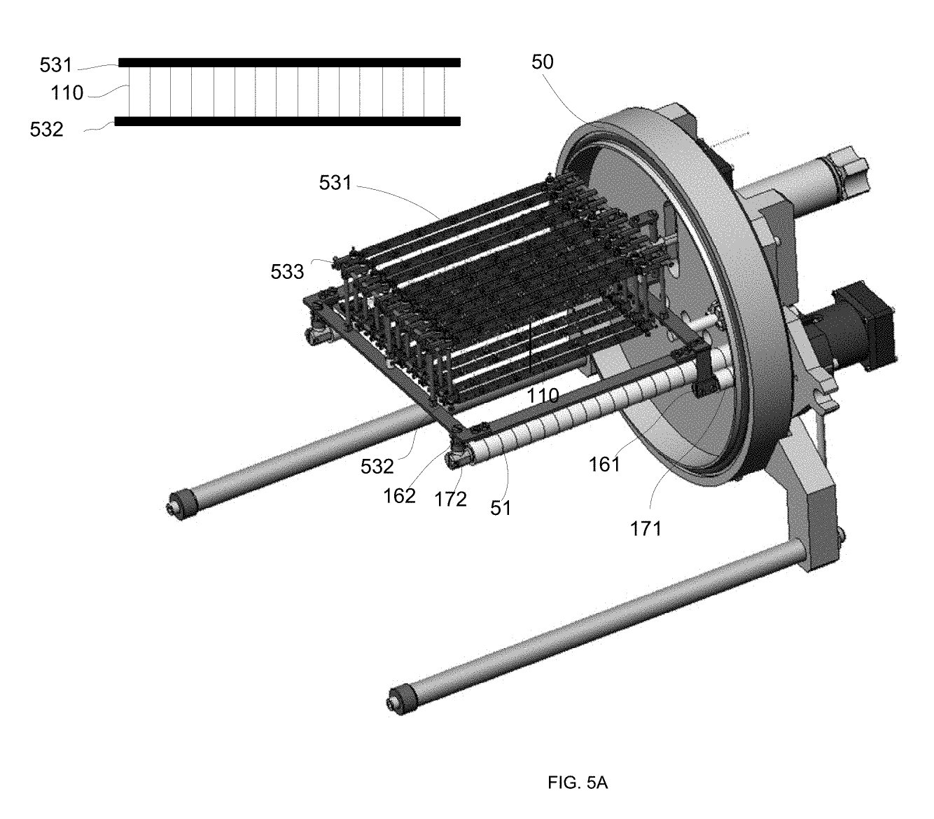

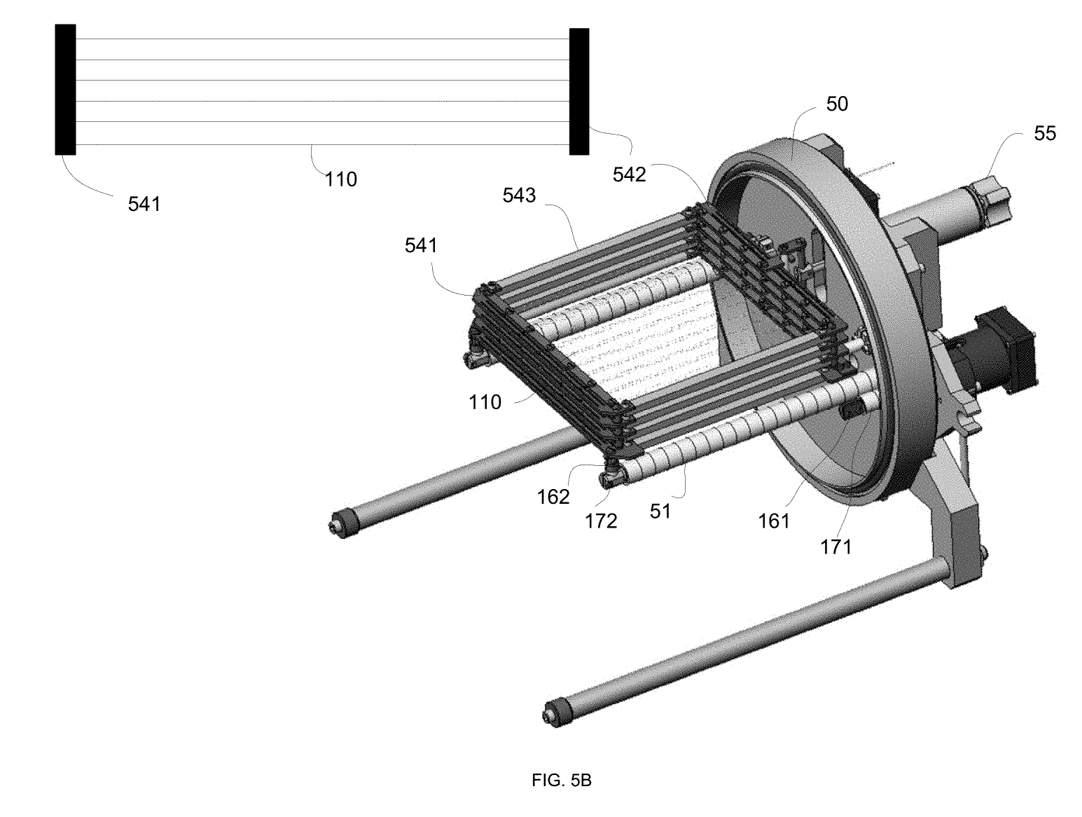

FIG. 5 illustrates the same filaments door 50 with different filament stages and, each mounted to the door 50 via filament stage supporting prongs 51, which as best seen in FIG. 2, protrude from the door's surface facing the interior of the reactor chamber. The filament stage supporting prongs 51 are configured for detachably mounting thereon each of the filaments stages with the filaments arrays so that, when the door 50 sealingly closes the opening 12 of the reactor chamber 2, and the prongs protrude horizontally into the interior of the reactor chamber, the filaments are disposed in the reactor chamber at a location and orientation as desired for the specific application.

FIG. 5A illustrates vertical filaments 110 while FIG. 5B illustrates horizontal filaments 110. The filaments may have any orientation.

In the upper part of FIG. 5 the filaments door 50 is shown with the filament stage supporting prongs 51 holding the filaments stage thereon, comprising an upper array 531 and a lower array 532 of filament holders. Spacers 533 may support the upper array.

When the door 50 sealingly closes the opening 12, the filaments together with their holding frames have a vertical orientation and are disposed at the upper part of the chamber. The vertical orientation can be particularly suitable for a 3D HF CVD on substantially elongated substrates extending generally vertically, i.e. perpendicular to a horizontal plane passing through the axis X.

In the lower part of FIG. 5 the filaments door 50 is shown with the filament stage supporting prongs 51 holding the filaments stage thereon, comprising a right array 542 and a left array 541 of filament holders.

When the door 50 sealingly closes the opening 12, the filaments together with their holding frames have a substantially horizontal orientation. This horizontal orientation can be suitable for either a 2D HF CVD on substantially planar substrates, such as e.g. semiconductor wafers, which extend horizontally, or a 3D HF CVD on substantially elongated substrates extending generally vertically.

Filaments modules in the reactor according to the presently disclosed subject matter can be configured to maintain a predefined tension of the filaments during preparation and the CVD processes. The tensioning method can vary depending on the orientation of the filaments. For example, when the filaments extend between two opposite sides of filament holders, e.g. two opposite beams, the tensioning can be provided by the movement of one side of each filaments holder away from its other side.

Thus, for the vertical filaments layout, the lower array 532 can be freely movable, e.g. by an externally applied force or under its own weight, in the downward direction, i.e. away from the upper array 531. For the horizontal filaments layout, the tensioning system can include a tensioning regulator 55 mounted to the filaments door at its outer surface, which can extend through the filaments door and be configured to pull the beams of the right array 542 that are disposed adjacent the inner surface of the filaments door.

FIGS. 5A and 5B also shows interfaces such as 171 and 172 that may be detachably connected (for example by screws) to interchangeable adaptors 161 and 162.

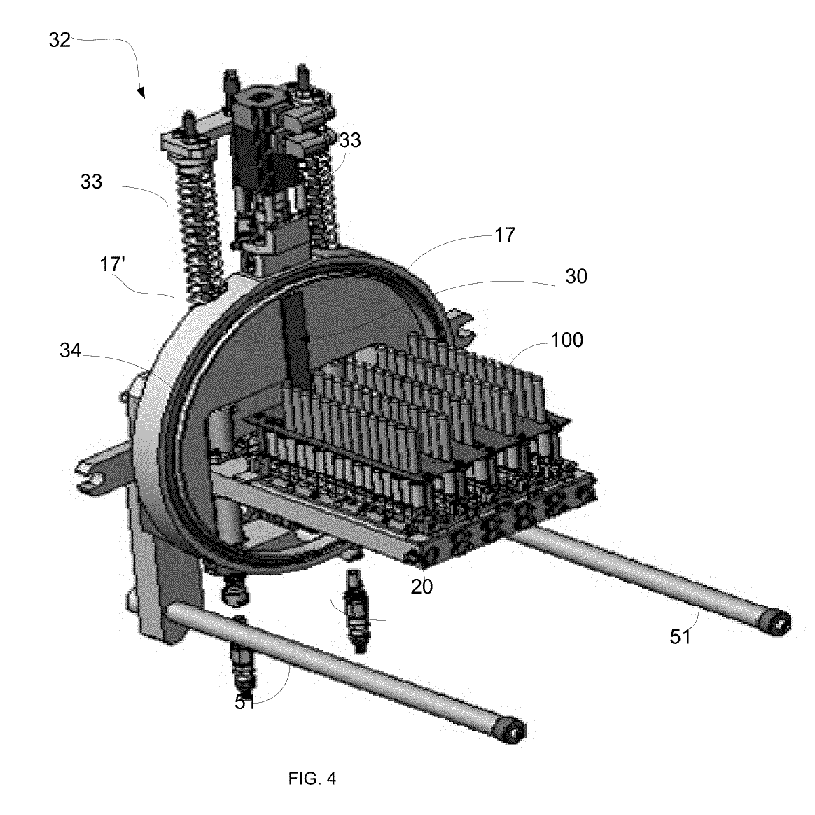

Reverting to FIGS. 1 and 2, the open end 11 of the reactor chamber 2 is the one to which interchangeable substrate modules generally designated by reference numeral 3, are mountable as shown in FIG. 1, with a possibility of being detached from the reactor chamber as shown in FIG. 2, for replacement by another substrate module. Each substrate module comprises a door generally designated as 10 and substrates stage 20 (not fully seen in FIGS. 1 and 2) mounted thereon. Examples of a substrate module 3 is shown in FIG. 4 where the door 10 of the substrate module 3 is configured for holding vertically extending elongated substrates 100. It should be noted that the substrate module may be configured for holding horizontally extending substantially planar substrates 100.

The substrate module 3, each of which comprises the door 10 configured to be detachably mounted to the open end 11 of the reactor chamber 2, have a structure which will now be described in more detail, using the same reference numerals for similar or identical components of the two modules and different reference numerals where the modules have different components or components having the same function but different configurations.

As seen in the examples shown in FIG. 4, the substrate module 3 may include:
a. The substrates door 10 configured to close hermetically the substrate module opening 11;
b. substrates stage 20, on which substrates 100 are positioned by virtue of substrates holders 22;
c. a vertical positioning system 30, on which the substrates stage 20 is mounted so as to enable a controlled vertical sliding motion of the stage relative to the door; and
d. a fluid cooling system that circulates a coolant via the substrate door 10 to the stage 20 for reducing heat absorbed by the substrates stage and the substrates.

The substrates door comprises an inner surface facing the interior of the reactor chamber during the operational state in which it is mounted to the chamber, an outer surface facing opposite to the inner surface, and a rim 17 in between the inner and the outer surfaces.

The vertical positioning system 30 comprises linear guides integrated vertically within the substrates door 10. The linear guides 32 comprise a static rail 33 fixed at its one end, for example, to the door or an extension of the door, and a movable rigid sleeve 34 slideably articulated on the rail or its other end.

The sleeve can have a motion range which is entirely within the interior portion of the door or an extended range in which the sleeve can move through openings at the doors' rim 17.

The substrates stage 20 is fixed to the sleeves of the linear guides so as to enable the substrate stage to be moved vertically relative to the door between two extreme positions:
a lowermost position, at which the substrate stage is maximally spaced from the high heat zone when the substrates are not intended to undergo the HF CVD; and
an uppermost position, at which the substrate stage is disposed at a minimal space from the high heat zone for performing the HF CVD on the substrates.

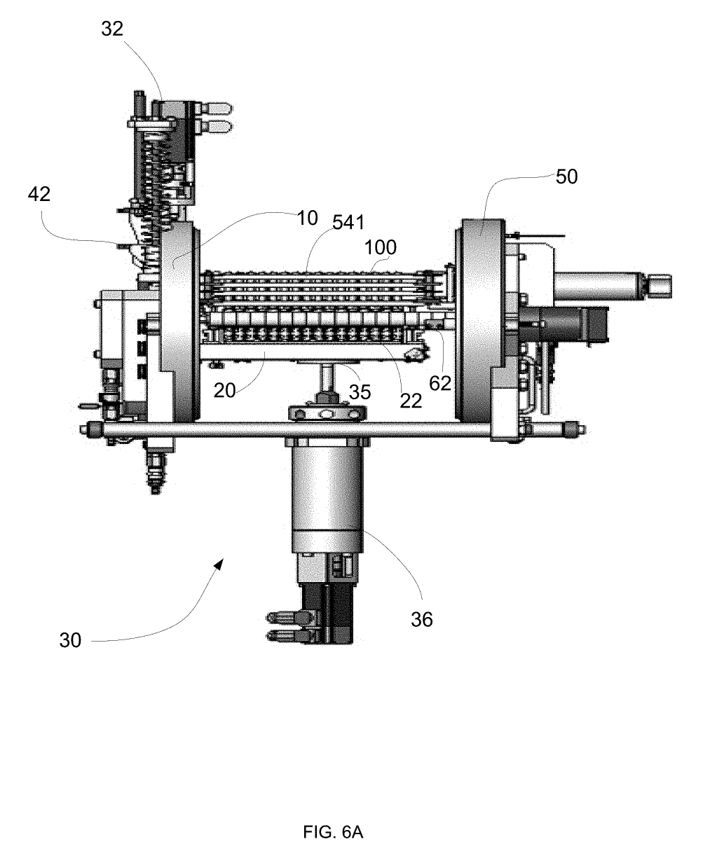

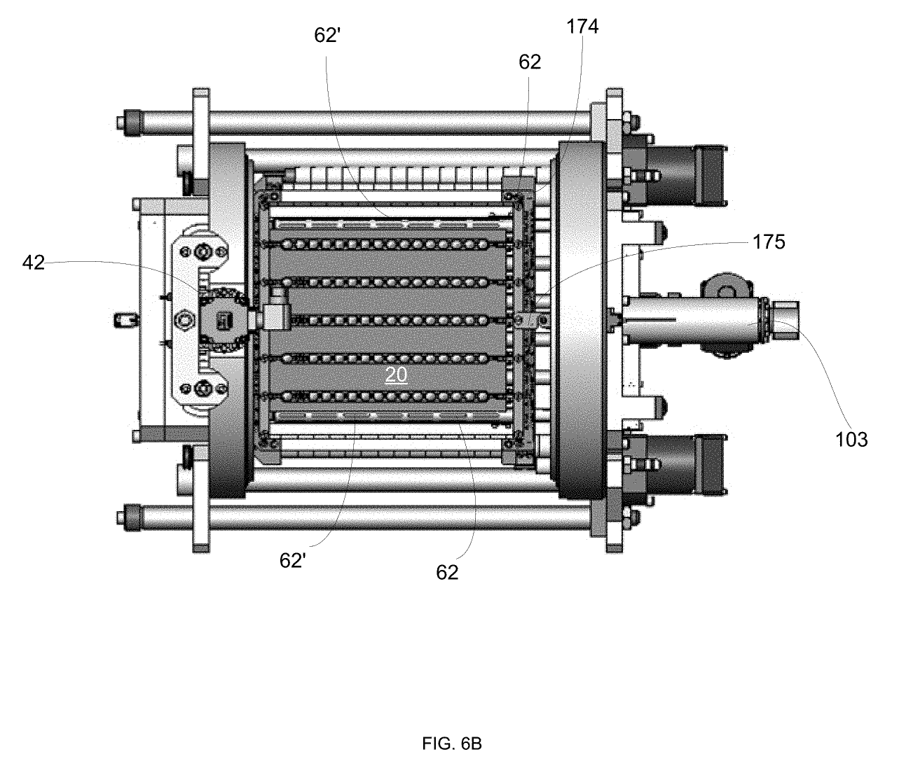

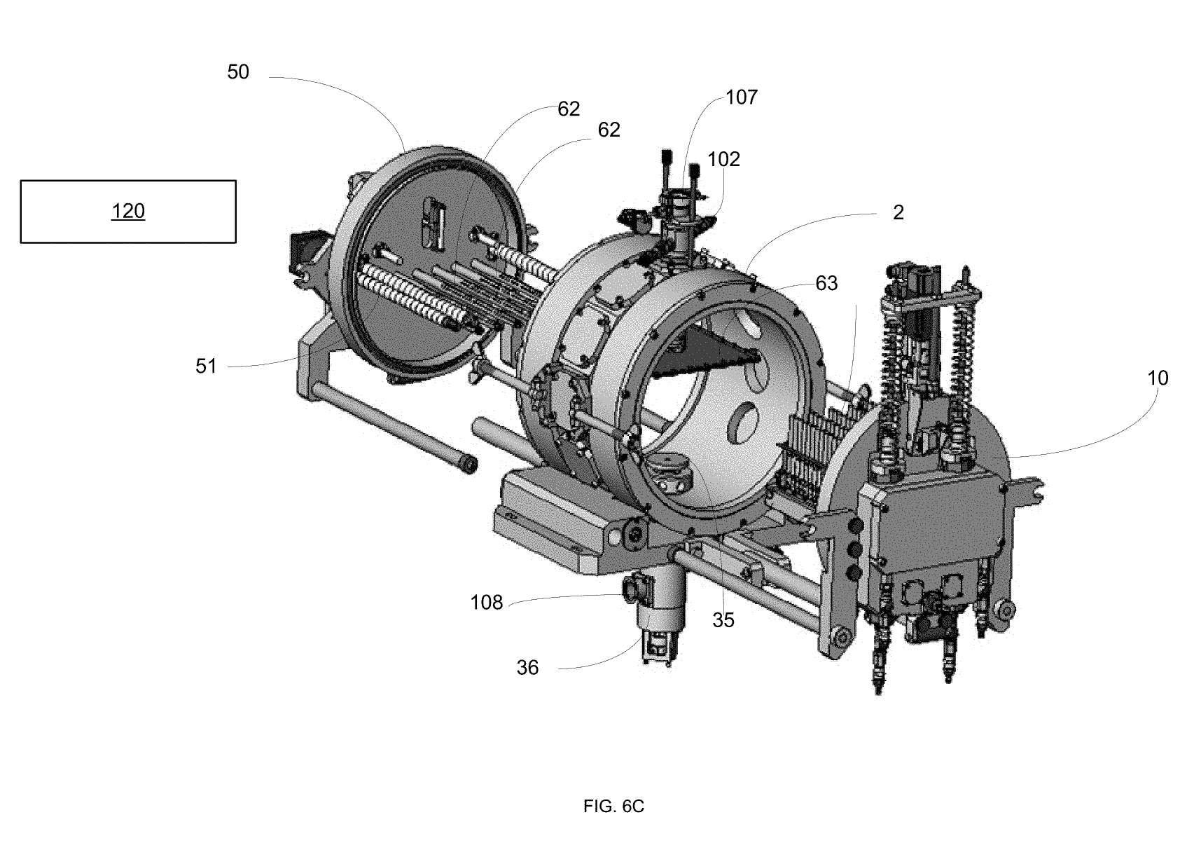

The substrates stage can be moved into the uppermost position by the application thereto of an upwardly directed pushing or pulling force and moved into and maintained at the lowermost position by virtue of its own weight. The reactor can have any means for controllably moving the substrates stage of each substrate module along its linear guides. One example of such means is a positioning jack, e.g. such as a jack 35 shown in FIGS. 6A and 6C, configured to abut the substrates stage from below and movable within the lower part of the chamber 2, to push the substrates stage upwardly. The jack 35 can be operated from the exterior of the chamber, e.g. by a jack drive 36 located outside the reactor chamber, e.g. within the base frame 101 seen in FIG. 1.

To facilitate the upwards movement of the substrate stage along the guides 32, the vertical positioning system can be springed by further comprising springs 39 engaged to the sleeves 34 or the substrates stage 20 from either above or below the stage. When located under the stage, the springs will be compressed when the stage is at its lowermost position and exert a pushing force on the substrates stage to facilitate the lifting of the substrates stage by the jack, and when located above the stage, for example, as seen in FIGS. 6A and 6C, the springs will be expanded when the stage is at its lowermost position and exert a pulling force on the substrates stage to facilitate the lifting of the substrates stage by the jack.

A controller (not shown in the drawings) can be used for automatically operating the positioning system based on pre-programmed instructions or on measurements from at least one associated measuring device or sensor, e.g. a device for measuring the substrates' temperature.

A fluid cooling system is configured to circulate a coolant through the sleeves 34 of the linear guides 32, wherein the sleeves are configured and sealed to contain a coolant fluid received or being discharged through fluid ports located at the end of the sleeve opposite to the rail. The fluid ports can be connectable to extendable or flexible hoses in order to allow a vertical motion of the sleeve as of the vertical positioning system.

The substrates stage 20 comprises internal fluid circulation channels (not seen in the drawings) in fluid communication with the sleeves.

In the embodiment described in FIGS. 4A and 4B, the substrates door module 3 may include two linear guides with sleeves 34.

The first sleeve may include a fluid introduction port to provide a coolant fluid into the sleeve and a stage port (not seen in the drawings) to provide a coolant to the stage fluid circulation channels therethrough.

The second sleeve may include a stage port (not seen in the drawings) to receive a coolant circulated within the stage fluid circulation channels therethrough and a fluid discharge port to discharge circulated fluid.

The substrate module can further include a substrates rotation system 40 to enable a rotation of each substrates holder 22, e.g. around its vertical axis. The substrates rotation system comprises: a drive 42 integrated into the substrates door 10, a stage gear system 46 incorporated into the substrates stage 20 and rotatable directly or indirectly by the drive, and substrates holders 22 configured to be mounted via the stage to the stage gear.

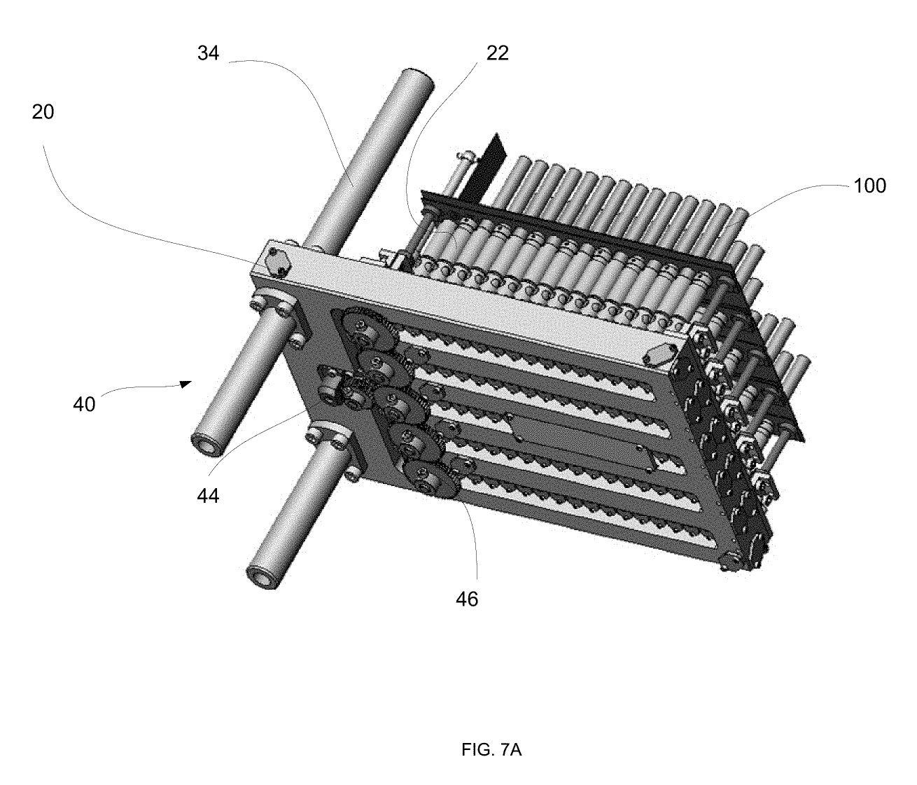

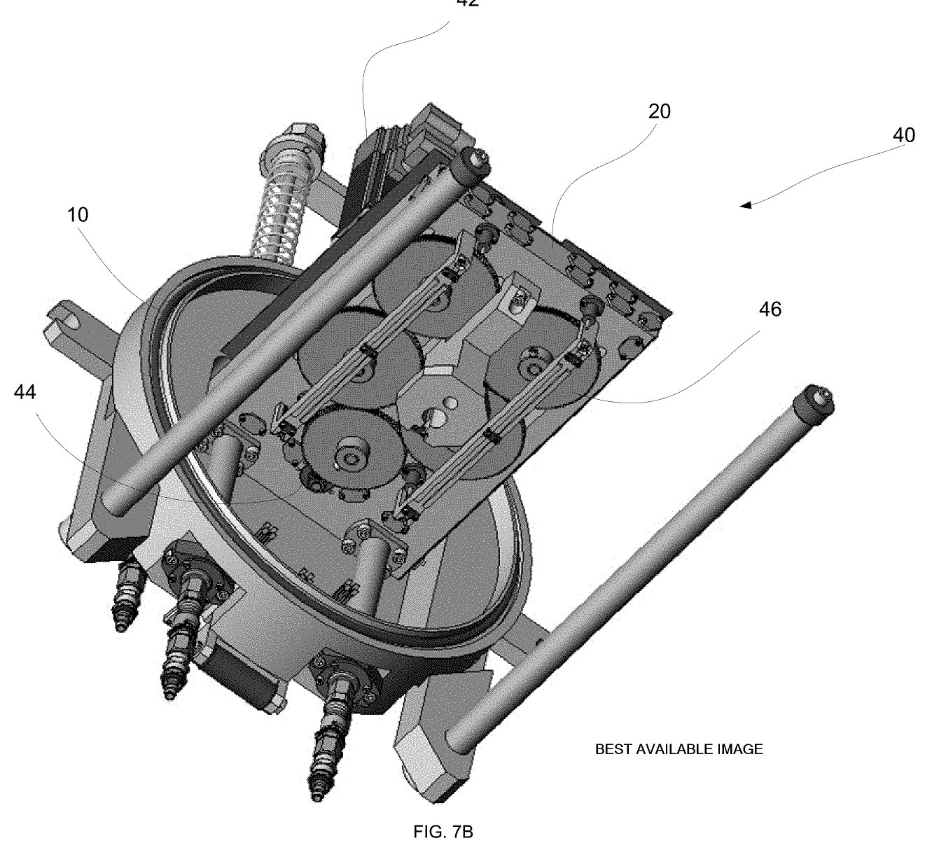

In the embodiments described in FIGS. 4, 7A and 7B the substrates rotation system comprises a drive 42, which rotates a drive shaft 44 that interengages and transfers the rotation to the stage gear 46. Each line of substrate holders is mechanically coupled to a stage gear 46 so that a rotation of the stage gear 46 rotates the substrates holders 22 of that row. Any mechanical coupling between the substrate holders and a rotating element may be used.

The gear wheels can be constructed and positioned within the stage gear system to transfer the rotation in parallel and/or in serial to fit a particular application.

The drive 42 can control the general rotation speed of the rotation system 40. In addition, the angular velocity can vary between substrates holders 22, hence between the substrates placed within the holders, by modifying the ratios of the stage gear.

The drive shaft 44 can be telescopic to maintain a continuous engagement with the stage gear when the vertical position of the substrates stage is modified.

It should be noted that different substrate holders may be rotated independently from each other. This may be achieved by using different rotating elements for these substrate holders.

As mentioned above, the reactor comprises a plurality of chamber ports formed in the peripheral wall 14 of the reactor chamber 2, and those of them that are seen in FIGS. 1 and 2 are each closed by a sealing cover 15, and those that are seen in FIG. 3 are designated by reference numerals 13 and each shown without the cover 15. At least some of the chamber ports can be configured for mounting therein an element, such a manifold or a nozzle, connectable to an external gas source, for introducing gas into the interior of the chamber and at least one other chamber port can be connectable to a vacuum source for extracting gas out of the chamber, for creating together the gas flow as described above thus constituting a part of the gas distribution system of the reactor. The gas-introduction and vacuum ports of the chamber can be spaced from each other as desired.

For example, the gas introduction port/s can be disposed in the upper part of the reactor chamber above the filaments stage, and the vacuum port/s can be disposed below the filaments stage, e.g. at the lower part of the reactor chamber.

In addition, or alternatively to the chamber ports and their associated elements, by virtue of which the above gas flow functions can be performed, the substrate modules and/or the filament module can be formed with a manifold also constituting a part of the gas distribution system and connectable, via a door port, to corresponding gas and/or vacuum source/s for participating in performing at least one of the gas flow functions. For example, the filaments module can be formed with such manifold, disposed in, above, or under the filaments stage, and can have a filament door port accessible at an outer surface of the filaments door and configured for being connected with an exterior gas or vacuum source.

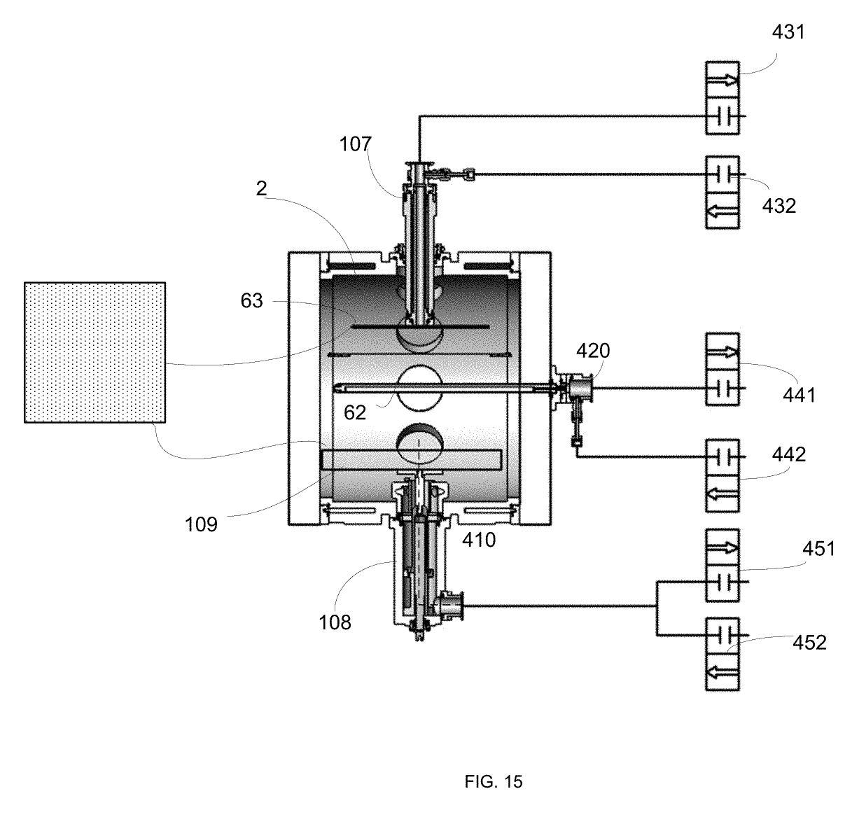

In the examples of the reactor embodiments shown in FIGS. 6C and 15, the gas distribution system comprises an upper gas/vacuum unit 107 disposed at the top of the chamber 2, a lower gas/vacuum unit 108 disposed at the bottom of the chamber 2, and a side gas/vacuum unit 420 disposed at a side of the chamber 2. Each gas/vacuum unit (107, 108 and 420) may be fed by vacuum (from modules 431, 441 and 451 respectively) and/or by one or more gases (from modules 432, 442 and 452 respectively).

Modules 431, 432, 441, 442, 451 and 452 may be valves or include valves.

In FIGS. 6C and 15 the gas and/or vacuum are provided to gas/vacuum interfaces such as manifolds 63, 62 and 109 respectively. Each manifold may include an array (rectangle or any other shape) of openings and a diffuser for distributing the gas/vacuum between the openings.

The gas and/or vacuum may be supplied from units such as gas and vacuum pumps 102 and 103.

In FIGS. 6C and 15, manifold 63 is disposed within the upper part of the chamber. In these figures manifold 62 may be mounted under the filaments stage 52 and a filament door port 56 in the filaments door 50 connectable to an external vacuum pump 102. Each manifold comprises a plurality of conduits with respective openings.

The positioning of manifolds 62 and 63 can be configured in order to allow at least one of their openings to reside in proximity to at least one set of heating filaments, for example, at a distance, which is not greater than the distance between two adjacent filaments.

The chamber and/or door ports intended for the introduction of gas into the reactor chamber can be connectable to different gas sources if desired.

The number of gas/vacuum unit exceeds one but may differ from three.

Each gas/vacuum unit may supply gas and/or vacuum.

By independently controlling modules 431, 432, 441, 442, 451 and 452 the amount and direction of gas and/or vacuum may be controlled. The direction of gas as well as the gases themselves that are supplied to chamber can be controlled using modules 431, 432, 441, 442, 451 and 452.

The manifolds may be moved in relation to the reactor by mechanical stages (for example z-axis movement) thereby changing the distance and/or orientation of the manifolds in relation to the substrates.

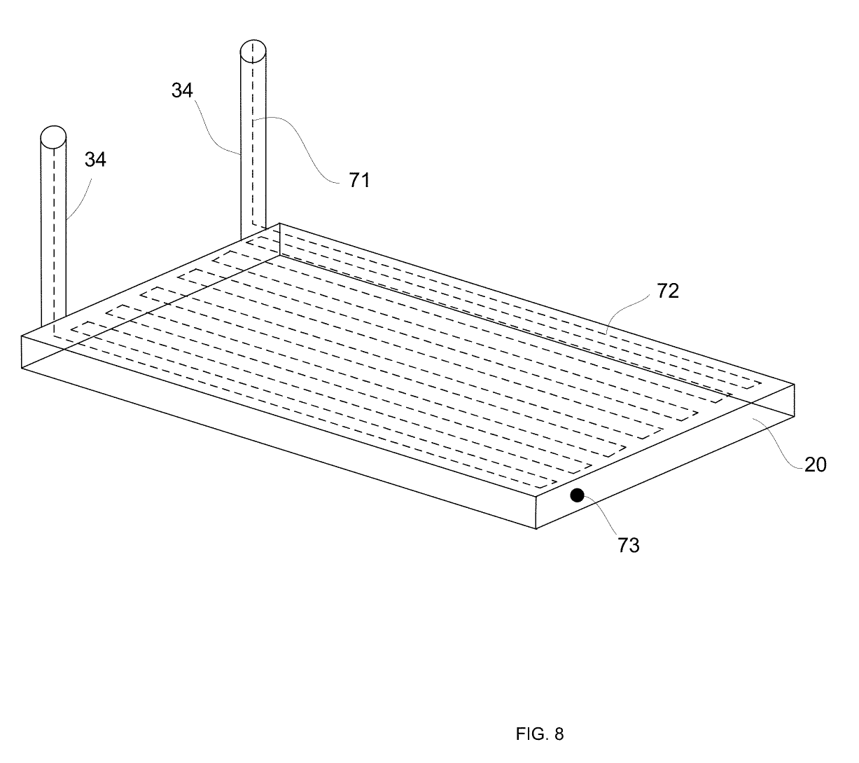

FIG. 8 illustrates a cooling system that include substrate conduits 72 that are positioned within substrate 22 and span along most of the substrate (FIG. 8 shown a raster scan pattern but other patters may be used). The substrate conduits 72 are fed by sleeve conduits 71 that are integrated in sleeve 34. The sleeve conduits may be fed by a fluid control system that may include plumps and/or valves and/or other conduits. FIG. 8 also illustrates a sensor 73 such as a temperature sensor.

Optionally, one or more of the ports formed in the chamber can be used for functions other than the gas flow functions described above. For example, they can be used for holding elements such as a window/windows for viewing the process, and/or sensor/sensors configured to obtain information regarding parameters of the process within the interior of the chamber.

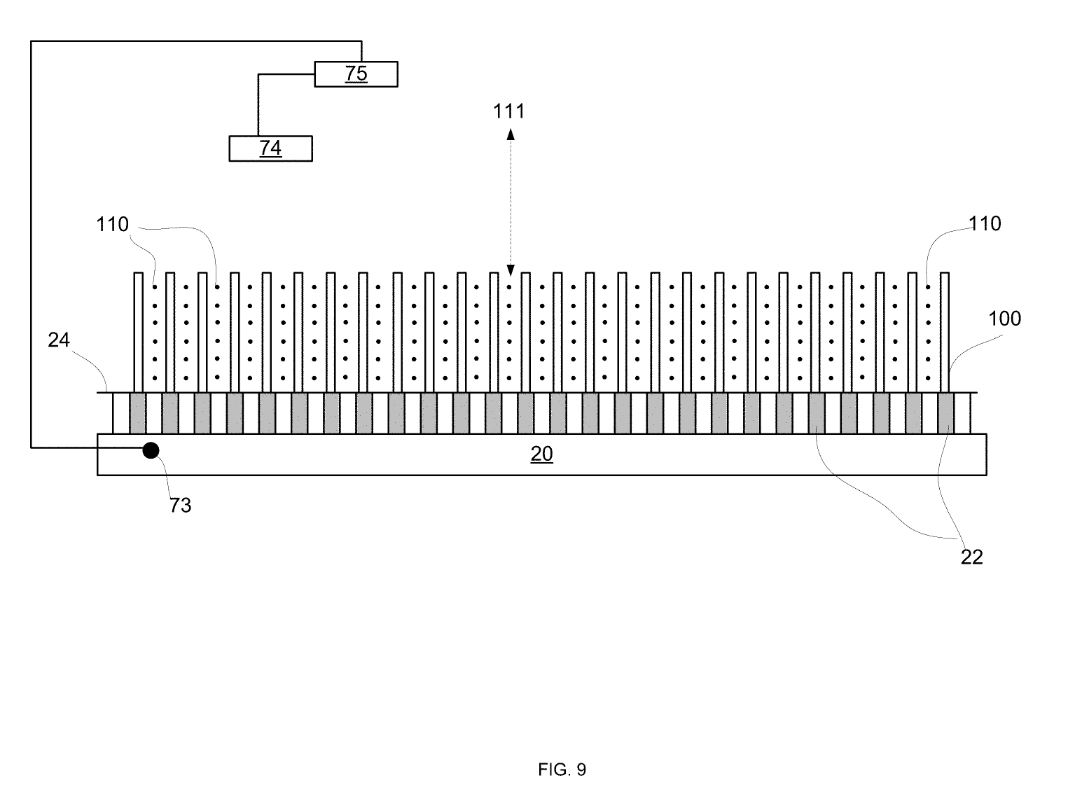

FIG. 9 illustrates an array of filaments 110 that are positioned between substrates 100. Substrates 100 are supported by substrate holders 22 that are supported by substrate stage 20. Substrate holders 22 may rotate about their axis thereby rotating substrate 100 in relation to filaments 100. Apertured frame 24 provided structural support to substrates 100 and/or substrate holders 22.

The substrates 100 of FIG. 9 are arranged in a rectangular grid. The filaments may stretch between rows of the grid or between columns of the grid. Thus—while FIG. 9-12 illustrate filaments that are normal to the drawings sheets, the filaments may be parallel to the drawings sheets.

FIG. 9 also illustrates temperature sensor 63 and another sensor such as an image sensor 74. Detection signals from the sensors are fed to controller 75. Controller 75 controls the chamber. For example, the controller may control the relative movement (dashed arrow 111) between array of filaments 110 and substrates 100.

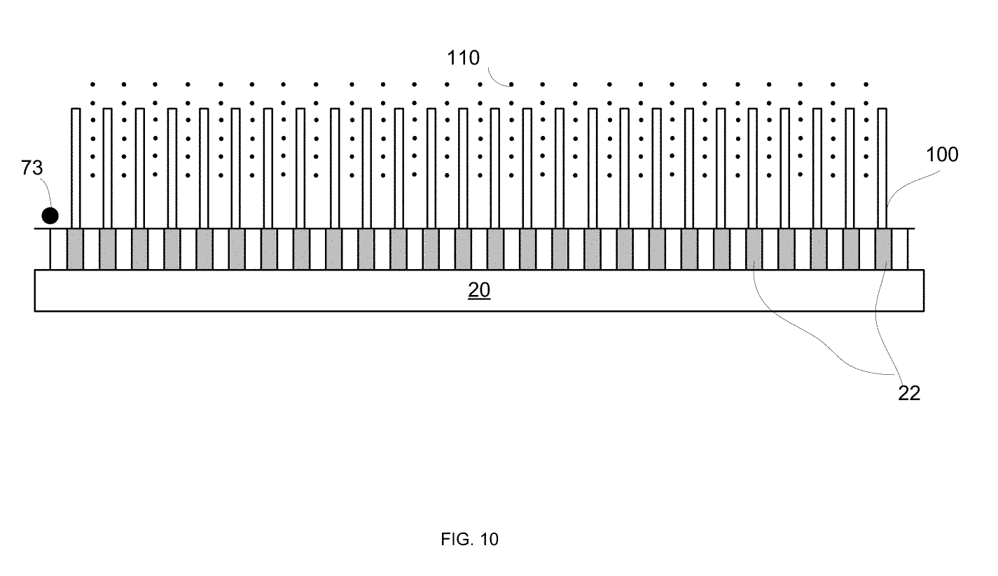

FIG. 10 illustrates array of filaments 110 as being partially positioned between substrates 100.

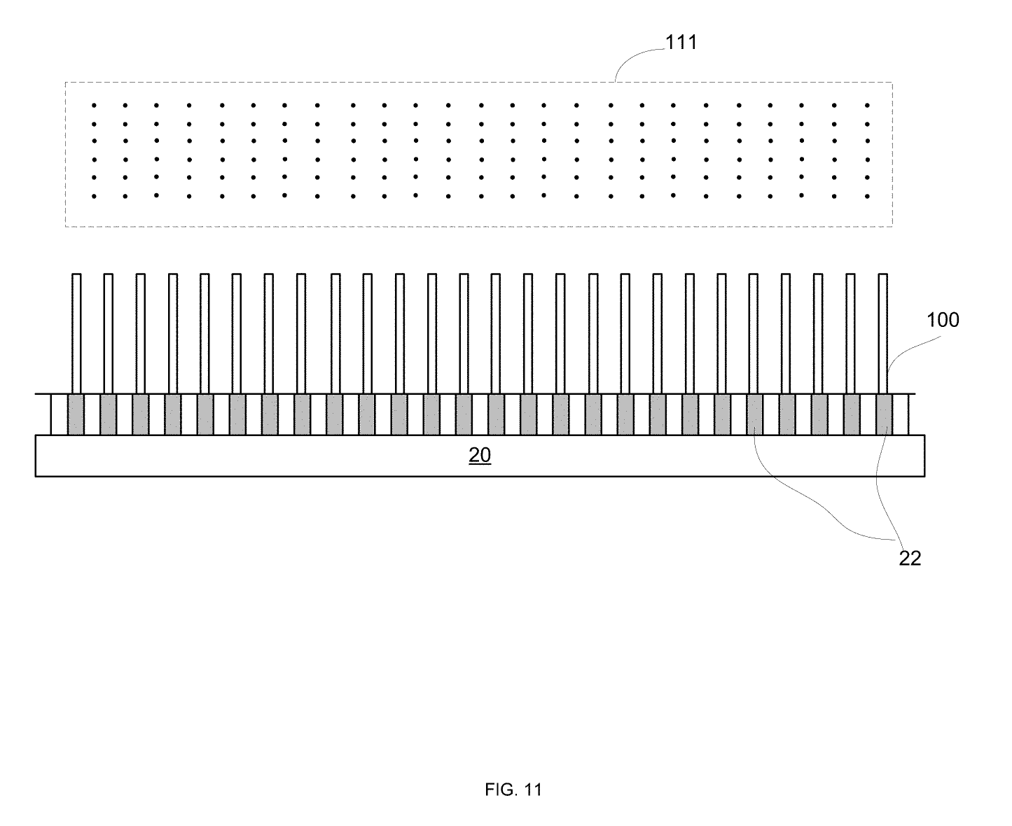

FIG. 11 illustrates substrates 100 as being positioned outside the energizing region 111 formed by the array of filaments 110. CVD gases may be ionized and/or broken up when passing through the energizing region.

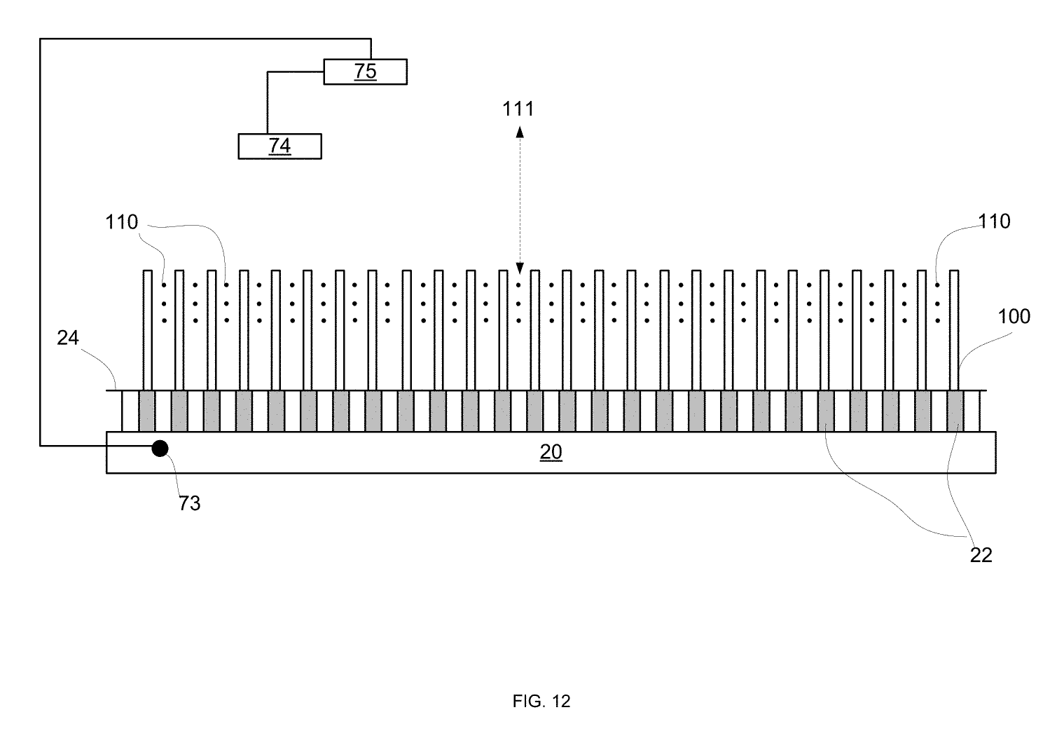

FIG. 12 illustrates an array of filaments 110 that is shorter that the array of FIG. 9. While the array of filaments of FIG. 9 spans along most (or all) of the length of substrates—the array of FIG. 12 is shorter and spans along a fraction of the length of substrates 100.

The following process steps can be performed prior, during and after the operation of the reactor as described above:

Preparation Steps:

a. preparing the substrate module comprising:
mounting the substrates holders on the stage;
mounting the substrates in the holders; and
sealingly mounting the substrate module to the corresponding opening in the reactor chamber.
   b. preparing the filaments module comprising:
assembling the filaments array on the filaments stage; and
sealingly mounting the filaments module to the corresponding opening in the reactor chamber.

Steps for Conditioning the Filaments:

a. making sure that the substrates stage is in its lowermost position;
b. heating of the filaments by electric current; and
c. introducing a gas mixture and applying vacuum to the interior of the chamber.

Steps of an optionally pre-conditioning of substrates.

HF CVD deposition process steps:

a. introducing gas/es and vacuum within chamber;
b. heating of the filaments by electric current;
c. moving the substrates stage into the uppermost position;
d. optionally, rotating substrates
e. operating the substrates stage cooling system;
f. terminating the process;
g. optionally, controlling the deposition process by thermal management of both filament and substrate temperatures, in conjunction with closed-loop pressure and gas flow control and substrate z-position

A Post-Operational Step:

a. Dissembling the substrate module from the reactor chamber and removing the processed substrates from the substrates stage.

There may be provided a reactor for a hot filament chemical vapor deposition on a plurality of substrates, the reactor may include a reactor chamber having one or more gas introduction ports for introducing a gas into its interior and one or more vacuum ports configured for applying therethrough a negative pressure to said interior for forcing a gas therein to flow in a direction towards and through the one or more vacuum ports; a filaments entrance opening configured to allow mounting therethrough a filaments stage configured to hold a set of heating filaments for creating a high heat zone within said chamber, in which said gas can be dissociated into gas radicals, when flowing in said direction; a substrate module opening spaced from the filaments entrance opening; and an interchangeable substrate module that may include (a) a substrates door having a preparation state, in which it is fully dismounted from said chamber, and an operational state, in which it is mounted to said chamber so as to close hermetically said substrate module opening; (b) vertical linear guides integrated within said door; (c) a substrates stage configured to at least indirectly hold said substrates and mounted to the door by means of the linear guides so as to enable sliding of the substrates stage between: (i) a first extreme position closest to the filaments stage for exposing the substrates to said radicals in the high heat zone and thereby allowing said chemical vapor deposition on the substrates; and (ii) a second extreme position farthest from the filaments stage for preventing the substrates from exposure to high heat in the high heat zone when the substrates are not intended to undergo hot filament chemical vapor deposition; and (c) a fluid cooling system configured to circulate a coolant through said linear guides and said substrate stage for reducing the heat absorbed by the substrates stage and the substrates.

The interchangeable substrate module may include a substrates rotation system that may include a drive integrated into the substrates door; a stage gear system incorporated into said substrates stage and rotatable at least indirectly by said drive; and one or more substrates holders configured to be mounted via the stage to the stage gear system and to be rotatable thereby.

The stage gear system is configured to enable some of the substrate holders to rotate in an angular velocity different than that of the other holders

At least one of the gas introduction ports or the vacuum ports extends inwardly into the interior of the reactor chamber.

Each of the gas introduction ports may be connectable to its corresponding gas source.

The reactor may include a filaments door mounted to the chamber at least during an operation of the reactor so as to close hermetically said filaments entrance opening of the reactor chamber, and at least one of the gas introduction ports or the vacuum ports is integrated within said filaments door

At least one of the gas ports is connectable to either a gas source or a vacuum pump interchangeably.

Each gas introduction port may include at least one egress opening and extends inwardly into the interior of the chamber to the extent allowing said opening to be located in proximity to the heating filaments at a distance, which is not greater than the distance between two adjacent filaments.

The reactor may include at least one temperature sensor configured to measure the temperature around the substrates and the distance between the filaments and the substrate stage is adjustable based on the temperature measured by said temperature sensor during the operation of the reactor.

The reactor may include a controller that determines the distance between the filaments and the substrate stage based on input received from said temperature sensor.

The reactor may include a positioning jack that is located within the reactor chamber and configured for contacting the substrates stage at a location thereof spaced from the door and for being moved in a vertical direction for moving the substrates stage with said guides between the extreme positions thereof.

The first extreme position of the substrates stage may be higher than the second extreme position thereof, and wherein said jack may be configured to exert on the substrates stage a pushing force to slide it to the first extreme position, and to release said force in order to allow the substrates stage to slide into the second position at least partially under the influence of gravity.

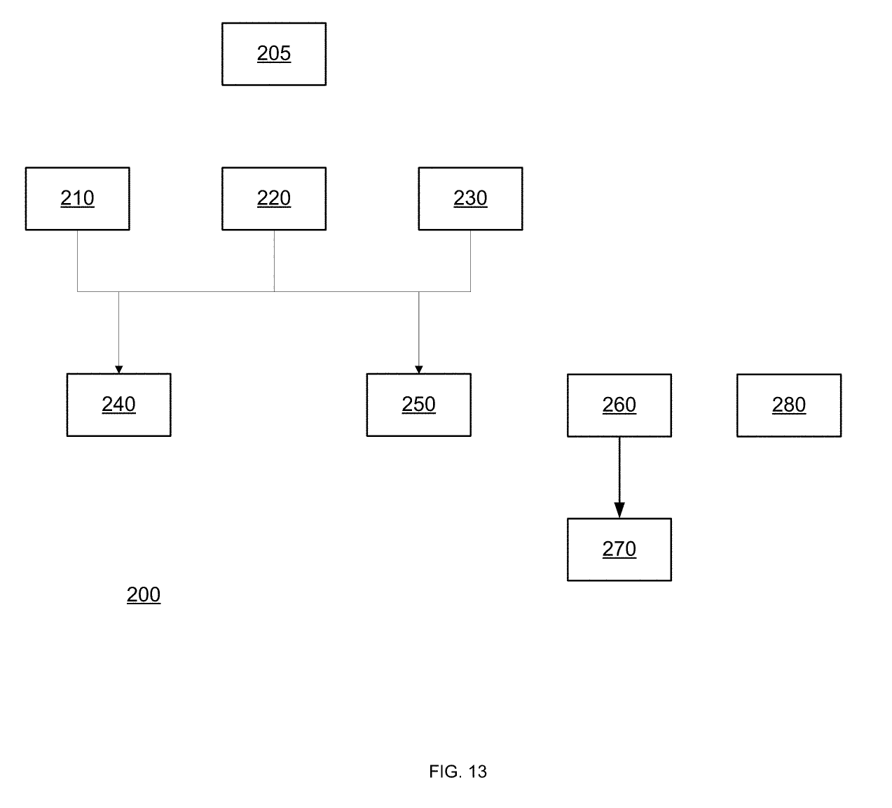

FIG. 13 illustrates an example of method 200.

Method 200 may include various steps.

Method 200 may include an initialization step 205.

Step 205 may include selecting one or more selected interchangeable adaptors out of a group of interchangeable adaptors that are removably coupled to the chamber. A first interchangeable adaptor of the group is mechanically coupled to the array of filaments. A second interchangeable adaptor of the group is mechanically coupled to the substrate support unit. The interchangeable adaptors may include, for example, a substrate stage.

The chamber may include interfaces (connecting elements that may be detachably connected to the interchangeable adaptors) for interfacing with each one of the group of interchangeable adaptors; wherein the interfaces are equal to each other. This allows to configure and reconfigure the chamber in a seamless manner. Furthermore—this allows to pipeline the CVD process and the interface configuration process. While a CVD process is applied on one or more substrates—another set of substrates that may be interfacing without other interfaces may be prepared.

Step 210 may include supporting, by a substrate support unit, at least one substrate.

Step 220 may include forming, by an array of filaments, positioned in the reactor, an energizing region.

Step 230 may include receiving, by a gas flow control unit that is coupled to multiple openings of a reactor, one or more CVD gases.

Steps 210, 220 and 230 may be followed by steps 240 and 250.

Step 240 may include directing, by the flow control unit, the one or more CVD gases at one or more predefined directions within the energizing region.

Step 250 may include introducing movement, by a movement system, between the array of filaments and the substrate support unit thereby selectively moving the at least one substrate in the energizing region and out of the energizing region.

Step 250 may include at least one of the following:
a. Scanning the array of substrates in relation to the energizing region thereby exposing, at different points of time, different parts of the substrate to the energizing region.
b. Scanning the array of substrates in relation to the energizing region thereby evenly exposing, at different points of time, different parts of the substrate to the energizing region.
c. Introducing movement between the linear arrays of substrates and the array of filaments; wherein during at least a part of the movement the filaments of the array of filaments are positioned between the linear arrays of the substrate.
d. Rotating, by the movement system, at least two substrates of the linear arrays.
e. Rotating, by the movement system, at least two substrates of the linear arrays about a rotation axis that is normal to the movement between the linear arrays and the array of filaments.
f. Independently controlling, by the movement system, a rotation of at least two substrates of the linear arrays.

The gas flow control unit may include gas conduits that comprise at least one gas conduit that has at least one opening. Step 240 may include positioning by the movement system, at least during one point in time the at least one gas conduit between the linear arrays; wherein the method comprises selectively dispersing at least one CVD gas between the linear arrays.

Method 200 may include steps 260, 270 and 280.

Step 260 may include sensing one or more CVD conditions.

Step 270 may include controlling the CVD process. Step 270 may or may not be responsive to the outcome of step 260.

Step 280 may include cooling the substrate support unit by a cooling system that comprises cooling fluid conduits that are positioned within the filament support unit.

Step 260 may include generating by a sensor an indication about a distance between at least one filament of the array and between at least one substrate.

The sensor may be a heat sensor that is thermally coupled to a substrate of the at least one substrate.

Step 270 may include controlling, by a controller, the movement system based on the indication about the distance.

Step 270 may include controlling, by a controller, a heat outputted by the filament based on the indication about the distance.

Step 260 may include sensing by multiple sensors, CVD conditions, and step 270 may include controlling, by a controller, at least one of the movement system, gas flow control unit and the array of filaments based on CVD conditions sensed by the multiple sensors.

The CVD conditions may include at least one out of a temperature of the array of filaments, a temperature of the at least one substrate, a flow of the CVD gases, and a spatial relationship between the array of filaments and the substrate support unit.

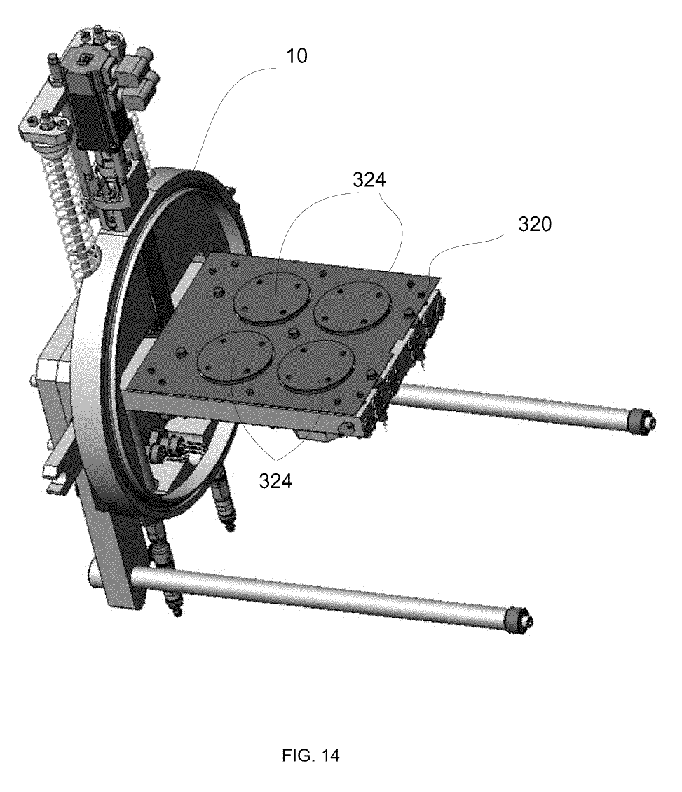

FIG. 14 illustrates examples of substrate module. Substrate stage 320 includes four elevated plates 324 for supporting 2D—substrates. The elevated plates 324 are circular but may have any other shape. The number of elevated plates may differ from four.

By changing the distance (for example using Z-axis movements) that spatial relationship between the substrates and the energizing region may be changed—the substrates may me moved in and out the energizing region. The temperature of the substrates may be affected by the temperature of the substrate stage 320, the temperature of the filaments and the distance between the substrates and the energizing region. Monitoring of the temperatures and/or the distance may control the manufacturing process of the substrates.

It should be noted that the reactor is configured to process different substrates—including three dimensional substrates and two-dimensional substrates.

By replacing substrates stages the reactor may process different types of substrates—for example replace between the substrate stages of FIGS. 14 and 7.

FIG. 14 illustrates a substrate stages for supporting 2D substrates

There may be provided a method for filaments conditioning by removing the substrate stage from the energizing region (for example by performing Z axis movements) and performing filaments conditioning process. The filament conditioning process may use different gases that those used during the manufacturing of substrates.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

Any reference to any of the terms “comprise”, “comprises”, “comprising” “including”, “may include” and “includes” may be applied to any of the terms “consists”, “consisting”, “consisting essentially of”.

Any reference to the phrase “may be” should also be interpreted as “may not be”.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “rear” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Those skilled in the art will recognize that the boundaries between various components are merely illustrative and that alternative embodiments may merge various components or impose an alternate decomposition of functionality upon various components. Thus, it is to be understood that the architectures depicted herein are merely exemplary, and that in fact many other architectures can be implemented which achieve the same functionality.

Any arrangement of components to achieve the same functionality is effectively “associated” such that the desired functionality is achieved. Hence, any two components herein combined to achieve a particular functionality can be seen as “associated with” Each other such that the desired functionality is achieved, irrespective of architectures or intermedial components. Likewise, any two components so associated can also be viewed as being “operably connected,” or “operably coupled,” to Each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps than those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

We claim:

1. A reactor for a hot filament chemical vapor deposition (CVD), the reactor comprising: an array of filaments; a substrate support unit that is configured to support at least one substrate; a chamber that comprises multiple openings; a gas flow control unit that is coupled to the multiple openings and is configured to receive one or more CVD gases and direct the one or more CVD gases at one or more predefined directions within an energizing region formed by the array of filaments; and a movement system that is configured to introduce a movement between the array of filaments and the substrate support unit thereby selectively moving the at least one substrate in the energizing region and out of the energizing region.

2. The reactor according to claim 1 comprising cooling system that comprises cooling fluid conduits that are positioned within a filament support unit.

3. The reactor according to claim 1 wherein movement system is configured to scan the array of substrates in relation to the energizing region thereby exposing, at different points of time, different parts of the substrate to the energizing region.

4. The reactor according to claim 1 wherein movement system is configured to scan the array of substrates in relation to the energizing region thereby evenly exposing, at different points of time, different parts of the substrate to the energizing region.

5. The reactor according to claim 1 wherein the at least one substrate comprises substrates that are arranged in linear arrays and wherein the movement system is configured to introduce a movement between the linear arrays of substrates and the array of filaments; wherein during at least a part of the movement the filaments of the array of filaments are positioned between the linear arrays of the substrate.

6. The reactor according to claim 5 wherein the movement system is further adapted to rotate at least two substrates of the linear arrays.

7. The reactor according to claim 5 wherein the movement system is further adapted to rotate at least two substrates of the linear arrays about a rotation axis that is normal to the movement between the linear arrays and the array of filaments.

8. The reactor according to claim 5 wherein the movement system is further adapted to independently control a rotation of at least two substrates of the linear arrays.

9. The reactor according to claim 5 wherein the gas flow control unit comprises gas conduits that comprise at least one gas conduit that has at least one opening, wherein the movement system is configured to position, at least during one point in time the at least one gas conduit between the linear arrays; wherein the at least one gas conduit is configured to selectively disperse at least one CVD gas between the linear arrays.

10. The reactor according to claim 1 further comprising a sensor, wherein the sensor is configured to generate an indication about a distance between at least one filament of the array and between at least one substrate.

11. The reactor according to claim 10 wherein the sensor is a heat sensor that is thermally coupled to a substrate of the at least one substrate.

12. The reactor according to claim 10 further comprising a controller that is configured to control the movement system based on the indication about the distance.

13. The reactor according to claim 10 further comprising a controller that is configured to control a heat outputted by the filament based on the indication about the distance.

14. The reactor according to claim 1 comprising a controller and multiple sensors, the multiple sensors are configured to sense CVD conditions and the controller is configured at least one of the movement system, gas flow control unit and the array of filaments based on CVD conditions sensed by the multiple sensors.

15. The reactor according to claim 14 wherein the CVD conditions are selected out of a temperature of the array of filaments, a temperature of the at least one substrate, a flow of the CVD gases, and a spatial relationship between the array of filaments and the substrate support unit.

16. The reactor according to claim 1 further comprising a group of interchangeable adaptors that are removably coupled to the chamber; wherein a first interchangeable adaptor of the group is mechanically coupled to the array of filaments; wherein a second interchangeable adaptor of the group is mechanically coupled to the substrate support unit

17. The reactor according to claim 15 wherein the chamber comprises interfaces for interfacing with each one of the group of interchangeable adaptors; wherein the interfaces are equal to each other.

18. A method for hot filament chemical vapor deposition (CVD) on at least one substrates, the method comprises: supporting, by a substrate support unit, at least one substrate; forming, by an array of filaments, positioned in the reactor, an energizing region; receiving, by a gas flow control unit that is coupled to multiple openings of a reactor, one or more CVD gases; directing, by the flow control unit, the one or more CVD gases at one or more predefined directions within the energizing region; and introducing movement, by a movement system, between the array of filaments and the substrate support unit thereby selectively moving the at least one substrate in the energizing region and out of the energizing region.

19. The method according to claim 18 comprising cooling the substrate support unit by a cooling system that comprises cooling fluid conduits that are positioned within the filament support unit.

20. The method according to claim 18 wherein the introducing movement comprises scanning the array of substrates in relation to the energizing region thereby exposing, at different points of time, different parts of the substrate to the energizing region.

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)
